(19) United States
(12) Patent Application Publication
(10) Pub. No.: US 2010/0090543 A1
(43) Pub. Date: Apr. 15, 2010

(54) PORTABLE TRANSFORMER AND METHOD FOR IMPROVING RELIABILITY OF ELECTRIC POWER DELIVERY

(75) Inventors: Geoffrey A. Cobb, Knoxville, TN (US); Eric J. Kauffman, Marietta, GA (US); Sterling R. Rosten, Alpharetta, GA (US); Ellen M. Dumas, Marietta, GA (US)

Correspondence Address: GE ENERGY GENERAL ELECTRIC;C/O ERNEST G. CUSICK, ONE RIVER ROAD, BLD. 43, ROOM 225, SCHENECTADY, NY, 12345, US

(73) Assignee: General Electric Company

(21) Appl. No.: 12/249,469

(22) Filed: Oct. 10, 2008

(51) Int. Cl. H05K 10/00

(52) U.S. Cl. 307/149

(57) ABSTRACT

The present invention relates to an apparatus and method for improving the transportation and installation of portable step-up power transformers for a power generating station due to failure or unavailability of installed step up transformers. A large MVA portable transformer may be used to alleviate or minimize these issues by being purpose built for transportability and commissioning speed. The portable transformer is transportable by road or lighter rail. Its size and weight are arranged to overcome restrictions such was weight limits, bridge constraints, and power line constraints. This device may also provide for rapid commissioning and decommissioning. This transformer may be a set of three single-phase units of sufficient size to be used as a generator step up transformer in three-phase operation.

### BACKGROUND OF THE INVENTION

The invention relates generally to improving the continuity and reliability of electric power delivery and more specifically to a large-scale portable power transformer trailerable over public roads and a method for using the portable power transformers to improve the continuity and reliability of power delivery for the electric utility user.

A transformer is a device in which, by electromagnetic induction, an alternating current (AC) of one voltage is transformed to another voltage, without change of frequency. Transformers are widely used in electrical apparatus of all kinds, and in particular in power transmission where high voltages and low currents are utilized.

A transformer has two coils, a primary for the input and a secondary for the output, wound on a common iron core. The ratio of the primary to the secondary voltages is directly proportional to the number of turns in the primary and secondary coils; the ratio of the currents is inversely proportional. A step-up type of transformer has more turnings on the secondary coil than on the primary coil and therefore the voltage induced in the secondary coil is larger than the primary coil voltage. If the number of turns on the primary coil is N_{P} and the number of turns on the secondary coil is N_{S}, and the respective voltages are V_{P} and V_{S}, then N_{S}/N_{P}=V_{S}/V_{P}. For example, if there are 200 turnings on the primary coil and 2,000 turnings on the secondary coil, then the voltage induced in the secondary coil is ten times larger than the primary coil voltage.

Large power transformers are an essential component in the delivery of electric power by an electrical utility. Delivery of power is initiated by a power generating station, which may include a fossil fuel station, a nuclear power plant or a renewable power source such as a windfarm. Electric power is provided from the generating station or a primary substation as three-phase ac power at different voltages, ranging from 13.1 kV to 22 kV. The electric power source may be connected to the low voltage (LV) or primary side of a three-phase transformer that steps up the voltage on its high voltage (HV) or secondary side to about 230 kV for a transmission grid. Other secondary side voltages that may be provided by different transformer configurations may include 115 kV or 345 kV.

The transformers must have sufficient capacity to accommodate the amount of power being provided by the generating station. The megawatt (MW) power rating of the generating station or the primary substation utilizing step-up transformers vary widely, but may include power generation in the 25 MW to 100 MW range and even up to over 500 MW. Transformer capacity may be rated in volt-amperes (VA), which is generally speaking a product of the magnitudes of voltage and current on the input side of the transformer. The large step-up transformers for a power station may be rated in Mega VA (MVA).

Because the step-up transformer occupies an in-line circuit path for the delivery of power from the generating station, unavailability of the transformer prevents the generating station from delivering power. Failure to deliver power results in loss of revenues and may also result in added costs to obtain replacement power from other power suppliers, potentially at higher per unit costs. Further, inability to deliver power reliably, as contracted, damages the reputation of the utility. Unavailability of the transformer may result from failure of installed transformers or the need by the utility to take the installed transformers out-of-service for preventive maintenance or modification.

In the event of failure of an installed generating station transformer, either a repair must be implemented or a replacement provided. These larger transformers are too heavy to be transported quickly and require significant permitting and logistics planning due to the large size and weight. They are not considered portable. They are often shipped on special purpose-built rail cars and with far too much weight to be transported by road. These transformers are also complex in their commissioning at site.

Mobile substation transformers have been used for lower MVA ranges, but these are not suitable for the large power generating station step-up transformers. Larger, more financially strong utilities have used spare transformers, either a full spare or an additional single-phase transformer, as a replacement of one of individual single-phase units that would be in service. However, for economic and other reasons it may not be desirable to maintain a spare unit on hand to address transformer outages.

Accordingly, there is a need to provide and utilize large-scale portable power transformer units that can be quickly and easily delivered to and installed at electric utility to restore electric power delivery for unplanned and planned outages of existing generator stepup transformers.

### BRIEF DESCRIPTION OF THE INVENTION

The present invention relates to an apparatus and method for improving the transportation and installation of portable generator step-up (GSU) power transformers for a power generating station due to failure or unavailability of installed step up transformers. A large MVA portable transformer may be used to alleviate or minimize these issues by being purpose built for transportability and commissioning speed. The portable transformer is transportable by road or lighter rail. Its size and weight are arranged to overcome restrictions such was weight limits, bridge constraints, and power line constraints. This device may also provide for rapid commissioning and decommissioning. This transformer may be a set of three single-phase units of sufficient size to be used as a generator step up transformer in three-phase operation.

Briefly in accordance with one aspect of the present invention, a method is provided for maintaining power transmission supplied normally through an installed generator stepup (GSU) transformer adapted for serving a primary generating station or a primary substation. The method includes providing portable spare single-phase GSU transformer units of suitable rating to replace at least one phase of an installed GSU transformer. The portable spare single-phase GSU transformer is sized to fit aboard an individual on-the-road trailer according to national transportation standards for on-road transport. For the United States, the national standards include U.S. Department of Transportation (U.S.D.O.T.) height, width and weight standards for on road transport. The method also includes storing the portable spare single-phase GSU transformers in at least one central location.

In accordance with another aspect of the present invention, a method is provided for maintaining power transmission normally supplied through an installed generator stepup (GSU) transformer, where the GSU transformer is adapted for serving a primary generating station or a primary substation. The method includes establishing an arrangement between a service provider and an operator for supporting continuity of power transmission through an installed GSU transformer. The method also includes maintaining an availability for one or more phases of a portable single-phase GSU transformer for replacing one or more phases of an installed GSU transformer. For a normal three-phase installed GSU transformer, replacement of all three phases with portable units is required. The method further includes providing services to the power generating entity for maintaining operability of the installed GSU transformer and expediting installation of at one or more phases of the portable single-phase GSU transformer in place of one or more phases of the installed GSU transformer.

In accordance with a third aspect of the present invention, s portable single-phase generator stepup (GSU) transformer arrangement is provided. The portable single-phase transformer arrangement is adapted for replacing the phases of a three-phase GSU transformer that may be used in a primary generating station or a primary substation. The GSU transformer arrangement includes a portable single-phase GSU transformer for at least one of a power generating station and a primary substation, sized to fit aboard an on-the-road trailer according to national transportation standards.

### BRIEF DESCRIPTION OF THE DRAWING

These and other features, aspects, and advantages of the present invention will become better understood when the following detailed description is read with reference to the accompanying drawings in which like characters represent like parts throughout the drawings, wherein:

FIG. 1 illustrates a front elevation view for an embodiment of the inventive portable single-phase GSU transformer unit;

FIG. 2 illustrates a top view for an embodiment of the inventive portable single-phase GSU transformer unit;

FIG. 3 illustrates an embodiment of the inventive portable single-phase GSU transformer arranged for transport atop an on-the-road trailer.

FIG. 4 illustrates an embodiment for the inventive portable single-phase GSU transformer unit to supply power to a transmission line from a power generating station.

FIG. 4A illustrates an embodiment for three portable single-phase GSU transformers configured as a replacement for a failed installed three-phase GSU step-up transformer;

FIG. 5 illustrates an arrangement of portable transformer units installed for supplementing load capacity of an installed and functioning GSU step-up transformer, which may be overloaded when operating alone;

FIG. 6 illustrates an arrangement of portable transformer units installed for temporarily replacing one installed three phase step-up transformer unit of a multi-unit step up transformer;

FIG. 7 illustrates an embodiment of the portable single-phase transformer unit to accommodate a generating station with rated MW and MVA output significantly below the rated MVA capacity of the replacement transformer units by matching impedance using current limiting reactors;

FIG. 8 illustrates another embodiment of an operational application for the portable single-phase transformer unit allowing continued operation with reduced MW output of a power generating station, which is above the combined rated MVA capacity of three portable single-phase transformer units operating in parallel;

FIG. 9 illustrates a further embodiment for the inventive portable single-phase transformer unit stacking multiple units in parallel to obtain a higher MVA capacity, in a configuration requiring higher MVA capacity;

FIG. 10 illustrates a connection for the portable single-phase GSU transformers to the installed iso-phase bus infrastructure;

FIG. 11 illustrates a connection for the portable single-phase GSU transformers to an installed iso-phase bus infrastructure; and

FIG. 12 illustrates an alternate connection between an existing iso-phase infrastructure to the portable single-phase GSU transformers using cable connections.

### DETAILED DESCRIPTION OF THE INVENTION

The following embodiments of the present invention have many advantages, including providing rapid access to large portable MVA generator step-up (GSU) transformer units quickly, thereby allowing replacement power for unavailable phases of an installed step-up transformer for a power generating station to be restored.

The inventive portable single-phase transformer unit may be provided in a range of outputs for augmenting or temporarily replacing installed equipment. Usually the portable transformers may be installed quickly, once on site. A present embodiment may be rated at about 70 MVA, however, other embodiments may up to 100 MVA or even larger.

This portable single-phase GSU transformer is transportable via road, rail, barge or other standard means so as to be utilized as a short cycle, return-to-service equipment replacement solution for generator step-up transformers and autotransformers. An advanced design permits optimal MVA and voltage selection within the lightest weight and smallest size possible. At the same time, the inventive portable single-phase transformer unit meets safety and reliability targets and shipping constraints. Unlike mobile substations, the inventive portable single-phase transformer units do not have primary and secondary switchgear, allowing the maximum shipping advantage for large MVA. Units are delivered without oil and require assembly and vacuum filling to be placed in service.

The portable single-phase GSU transformer unit may be used to provide a one-for-one replacement for one or more unavailable individual phases of an installed step-up transformer configured as three single-phase GSU transformers in parallel to provide a three-phase output. The portable single-phase GSU transformer unit may be used to provide a complete replacement for a unitary three-phase step-up transformer by providing three portable single-phase transformer units. This transformer solution is unique in that it is purpose-built for this application and configurable for multiple sites with disparate electrical requirements

Another application of the portable single-phase transformer unit is to maintain continuity of operation for overloaded multi-unit substations by adding the portable single-phase transformer units in parallel with the overloaded components.

In addition, the portable transformers may be provided as a supplement to installed step-up transformer units for service at peak demand as a temporary solution. The portable units may also permit overloaded two-unit substations to take a maintenance outage, with the load shifted to the temporarily installed portable transformer units.

Other benefits also include shorter outages. The portable single-phase transformer units can be transported quickly and easily. The portable single-phase transformer was designed to meet the strictest federal, state, and local transportation regulations to keep transportation permitting at a minimum. Transformers can be delivered on site in less than one week with an estimated installation time of two weeks from the time of deployment.

The inventive portable transformers may be fabricated to fit many typical applications, and customers can now replace transformers for an MVA size that previously wasn't available to them, including a small generator step-up or large primary substation.

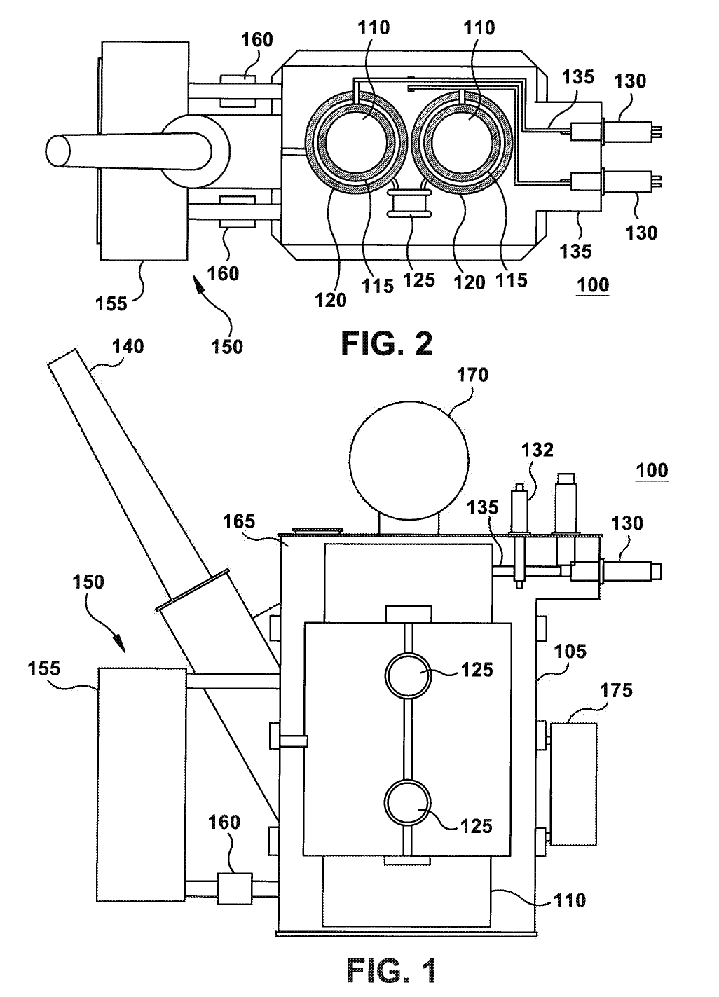

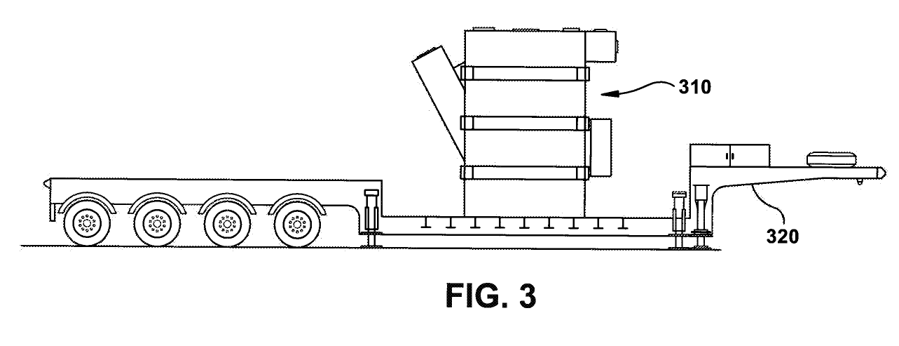

FIG. 1 illustrates a front elevation section for an embodiment of the portable single-phase transformer. FIG. 2 illustrates a top view for the embodiment of the portable single-phase transformer. A casing 105 for the transformer 100 houses a core 110 with a primary winding 115 and a secondary winding 120. Off-load tap changers 125 are provided for minor variation on the secondary voltages. Low voltage bushings 130 provide for connection to the output from the generator of the generating station (not shown). The low voltage bushings 130 are also internally connected through low voltage (primary) bus bars 135 to the primary windings 115. A low voltage neutral bushing 132 is also provided for the secondary voltage. Secondary windings 120 are connected to a high voltage bushing 140 that provides for connection to the transmission system for the site (not shown). The portable transformer 100 is provided with a cooling system 150. Transformer oil is circulated through an oil cooler 155 by oil circulating pumps 160 and though a tank 165 which houses the core 110, primary windings 115 and secondary windings 120. An oil preservation tank 170 maintains a head of oil on the casing 105. The transformer 100 may further include a control cabinet 175 for monitoring and control of transformer performance including transformer oil circulation and temperature monitoring.

The dimensions of the transformer are such that when three units are placed side by side they will have a minimal footprint so as to allow placement in reasonable proximity to the existing transformer connecting infrastructure.

Transformer tare weight (transformers less coolers and oil but including trailer and tractor weighs less than 20,000 lbs per axle. Other embodiments can be smaller or larger depending on transportation restrictions and methods. Each transformer will be 15 ft long, 7 ft wide, 13.5 feet tall to avoid interference with bridges, overpasses, and power lines. The shipping weight of each transformer is approximately 90,000 lbs (without oil). The total weight, with tractor and trailer, will be less than 20,000 lbs/axel. Loads under 20,000 lbs/axle require minimal permitting in most states. Transformers are designed to ship on a standard drop deck commercial trailer. The use of a standard commercial trailer reduces cost and allows the service provider flexibility in shipping transformers.

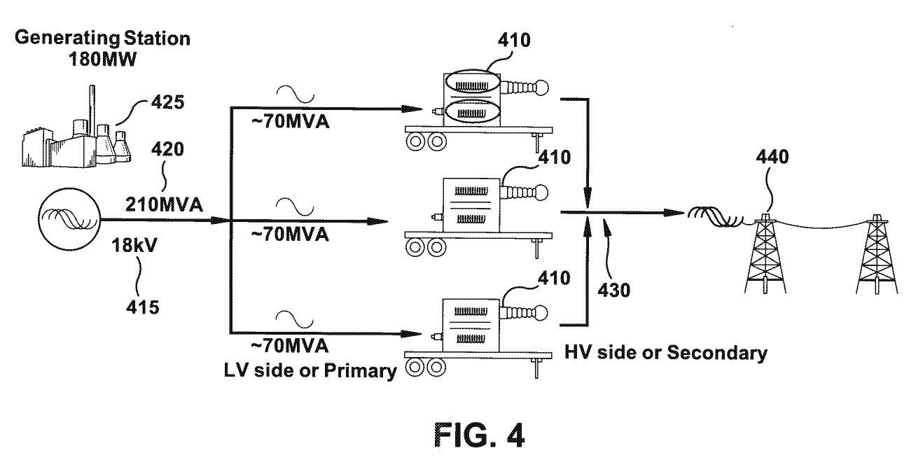

FIG. 3 illustrates, an embodiment of the inventive portable single-phase GSU transformer arranged for transport atop an on-the-road trailer. The portable single-phase GSU transformer 310 is shipped aboard the on-the-road trailer 320 without several components that would make transport unwieldy or potentially result in damage to the component. For example, components that are not installed for shipping include the high voltage bushing; the low voltage bushings; the neutral bushing; the oil preservation tank; and the oil cooler, pumps and piping.

The inventive portable single-phase GSU transformers may be used to replace one or more unavailable phases of the three-phase installed step-up transformer for the power generating stations. A transformer casing may include an external control panel for control of cooling and alarm functions associated with transformer

As previously described, the one embodiment of the portable single-phase GSU transformer may include a rating of about 70 MVA. The method for employing the portable transformer describes configurations based on a 70 MVA rating, however it should be understood, that other embodiments for the portable transformer are not limited to a 70 MVA output per phase.

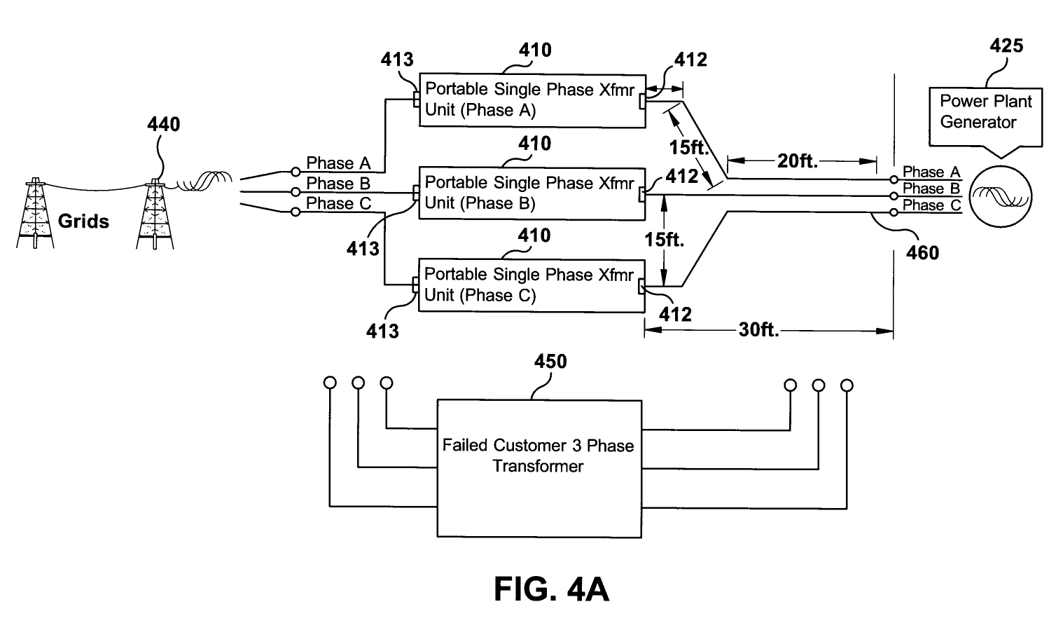

FIG. 4 illustrates an embodiment of an application for the inventive portable single-phase transformer. Three portable single-phase transformer units 410 are configured in parallel, acting to step-up an 18 kV output 415 of 210 MVA 420 from a 180 MW power generating station 425 and to provide a three-phase output at 230 KV 430 on the high voltage side to a transmission grid 440. Overall, the configuration may accept 210 MVA or about 180 MW at a power factor of about 0.85. The high voltage side may also provide high voltage taps capable of providing outputs of −5%, −2.5%, +2.5% and +5% of the nominal output voltage.

Further, the nominal primary and secondary voltages for the portable single-phase transformer are not limited to 18 kv on the primary and 230 kv on the secondary. Variants of the exemplary transformer may incorporate combinations of nominal primary side voltages of 13.1 kV-13.8 kV-15 kV, 18 kV and 22 kV with nominal secondary side voltages of 69 kV, 115 kV, 138 kV, 161 kV, 230 kV, 345 kV, and 500 kV.

FIG. 4A illustrates an embodiment for three portable single-phase GSU transformers configured as a replacement for a failed installed three-phase GSU step-up transformer. The three portable single-phase GSU transformers 410 are connected to the grid 400 on the high voltage side through high voltage bushings and to the power plant generators 425 on the low voltage side through the low voltage bushing 412 via temporary iso-bus 460.

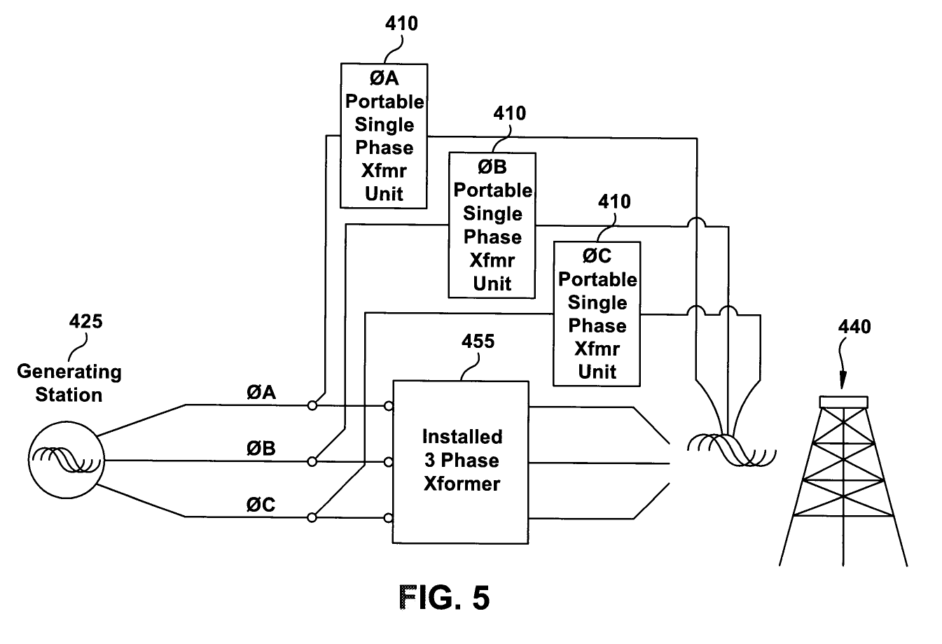

FIG. 5 illustrates an embodiment of an arrangement of the portable single-phase GSU transformers installed for supplementing load capacity of an installed and functioning step-up transformer, which may be overloaded when operating alone. The portable single-phase GSU transformers 410 are connected in parallel between the generating station 424 and the grid 440 with the installed three-phase transformer 455, which may be overloaded.

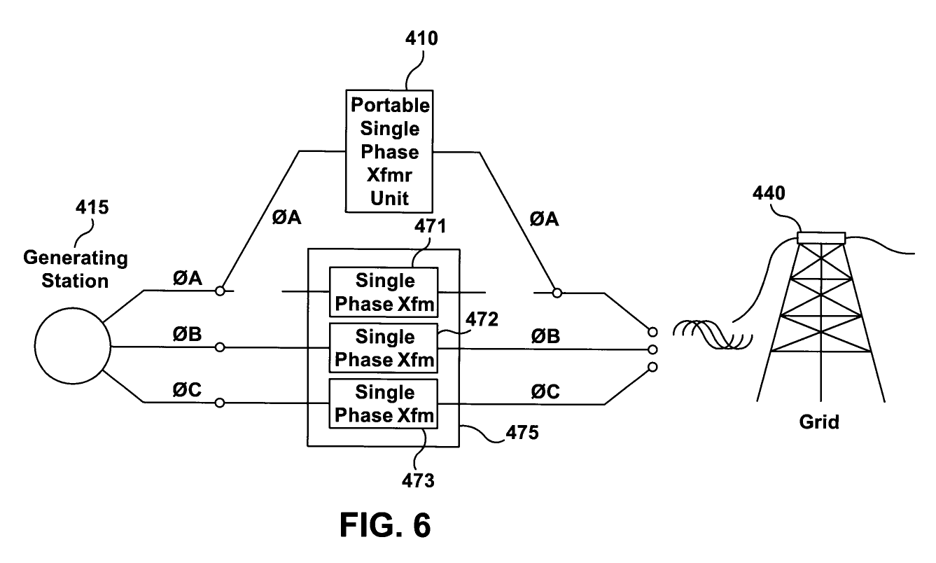

FIG. 6 illustrates an embodiment for arrangement for one portable single-phase GSU transformer 410 installed for temporarily replacing one installed single-phase step-up transformer 471 unit of a multi-unit single-phase step up transformer 475. The normally installed single-phase step-up transformer 471 is disconnected on the primary side and the secondary side and otherwise electrically isolated. The portable single-phase GSU transformer unit 410 is connected in its place to provide replacement load capacity. The temporary replacement may be made for failure or a planned maintenance outage on the installed transformer unit.

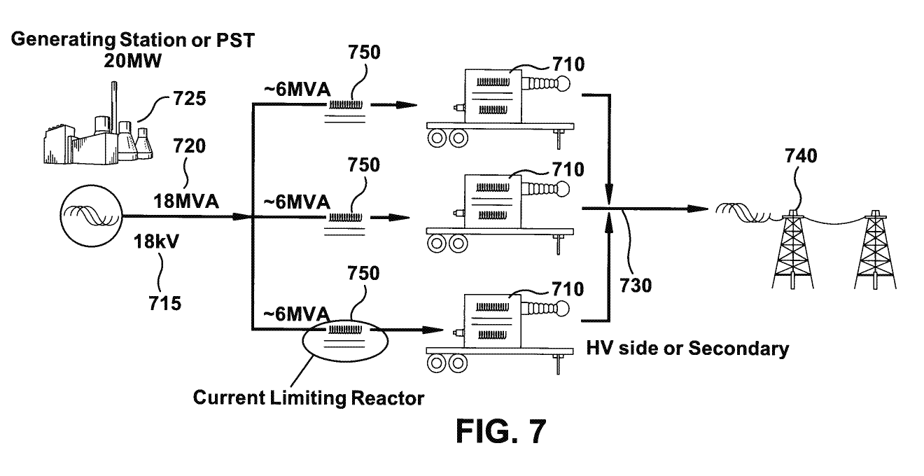

FIG. 7 illustrates an embodiment of the portable single-phase transformer unit to accommodate reduced MVA loads. Three portable single-phase GSU transformers 710 may be configured in parallel acting as a replacement for an unavailable three-phase step-up transformer unit that receives power from a power generation station 725 or primary substation with a rated MW and MVA output significantly below the rated MVA capacity of the replacement transformer units. Impedance, however becomes an issue. As the impedance goes down, the stress on the system, if a fault occurs, will go up. If a fault occurs with the portable single-phase transformer units installed, stress on the system may be many times that which would result in a normal configuration impedance. Current-limiting reactors 750 may be provided in line with the primary winding of the replacement transformers to limit fault current to acceptable levels.

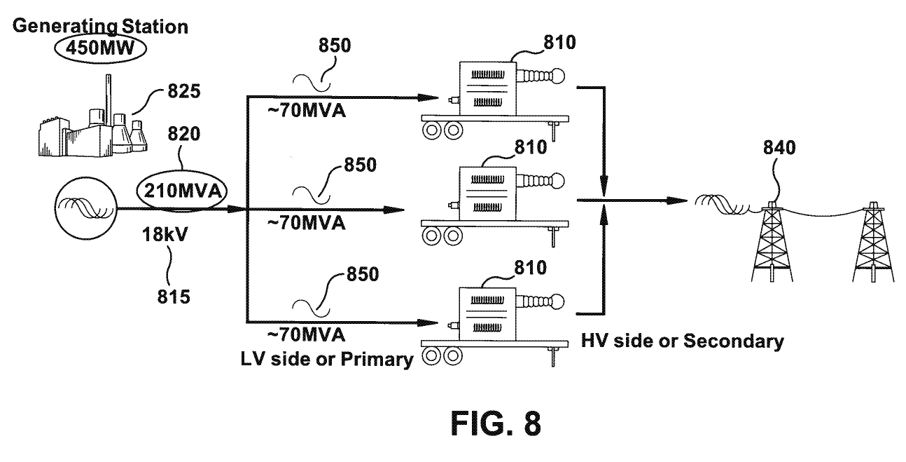

FIG. 8 illustrates another embodiment of an operational application for the inventive single-phase transformer unit. For a power generating station 825 with a 450 MW capacity operating at nominal power factor of about 0.85, may generate about 383 MVA, which is above the combined rated MVA capacity of three portable single-phase transformers 810 operating in parallel and individually rated at 70 MVA 850. In this circumstance, use of the three portable single-phase GSU transformers 810 may allow restored or continued operation of the power generating station albeit with reduced MW output for delivery to the grid 840, while satisfying the MVA limitations of the portable GSU transformers 810.

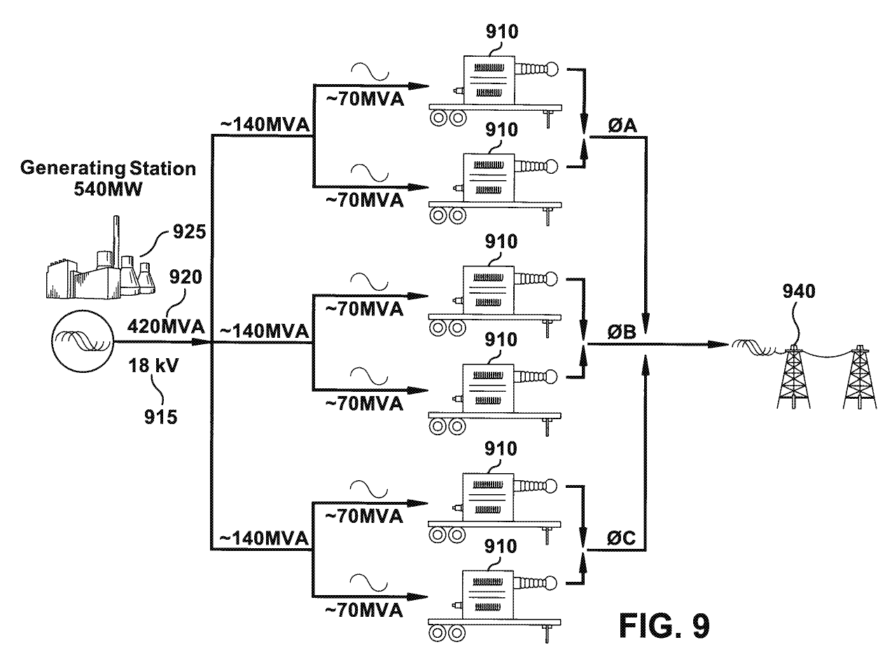

FIG. 9 illustrates a further embodiment for the inventive portable single-phase transformer unit in a configuration requiring higher MVA capacity. A power generating station 925 may output a power in the range of about 540 MW requires a step-up transformer for which the rated MVA capacity for each phase exceeds the capacity of the portable single-phase GSU transformer operating. In such a circumstance more than one portable single-phase transformer unit may connected in parallel for each unavailable phase of the installed step-up transformer to provide the required MVA capacity. As illustrated, each of phase A, phase B and phase C may be provided with the two portable single-phase GSU transformers 910 operating in parallel. Each phase will then be capable of transforming 140 MVA (combined rating of two portable single-phase transformer units).

A further aspect of the present invention includes a method for providing a temporary GSU spare for major or catastrophic failures of installed GSUs. The method is designed to solve key business issues for an operator of the GSU transformer, such as but not limited to an operator of an electric utility, an operator of a primary substation, and an operator of a power generating station, associated with a GSU failure. Specifically the method provides for mitigating the risk of prolonged business interruption and the associated revenue loss, reducing downtime when a failure occurs, and providing a spare option without a major capital expenditure.

The method may include a transformer reserve program (TRP) wherein an arrangement is established between a service provider and a power generating entity for supporting continuity of power transmission through a GSU transformer. The arrangement may provide for maintaining availability of a replacement GSU for replacing at least one phase of an installed GSU of the power generating entity. The arrangement may also include providing services to the power generating entity for preventing failure of an installed GSU transformer and for expediting replacement of one or more phases of the installed GSU)

The TRP may incorporate a contractual arrangement for a term. For economic viability, the term may extend from about 5 years to about 20 years and may be expected to average about 10 years. The arrangement may include a periodic fee for maintaining availability of one or more phases of a replacement GSU transformer and for expediting installation of one or more phases of a replacement GSU transformer. The periodic fee may include an an annual membership fee per each covered installed transformer. The arrangement may further include a periodic use fee, such as a weekly use fee, when using the temporary spare GSU transformer. The arrangement may also include charging a fee for services including one or more of assessing initial condition, continuing inspection, continuing monitoring, and performing preventive maintenance for the operator's installed GSU transformer, and providing technical advisory services for removal of the failed GSU transformer and replacement of the replacement GSU transformer.

The program may also provide availability type guarantee options for customers. Such guarantees may include, but not be limited to one or more features, such as “return to service” time (days) and “on-site delivery” time (days). In addition, the agreement could include all applicable terms and conditions, such as liquidated damages, limits of liability, etc.

Although such a method may be concentrated on a long-term “contractual lease” a one-time transactional rental may be provided, dependent upon the needs of the power generating entity and an ability to provide such support.

The TRP may include also provide a variety of services for fee to the power generating entity. A first service may include transformer condition assessments. The assessments may include a thorough analysis and report of the transformer condition. A transformer expert may review and evaluate the pertinent current data and documentation against baseline data to establish the health of each transformer. The health of each transformer may be used to prioritize the maintenance and monitoring needs of each unit. The assessment may rank probability factors against consequence factors to determine a transformer risk index (TRI).

The TRP may further include continued transformer monitoring, which will collect, analyze and diagnose certain parameters at a designated frequency to assess routine and preventative maintenance needs and other remedial actions.

The step of providing services may further include providing outage planning for the installed GSU transformer, wherein an outage includes a failure of the installed GSU transformer or a planned removal of at least one phase of the installed GSU transformer from service.

Outage planning provides a detailed plan of action at the facility level for each transformer included under the arrangement. The outage plan includes all necessary steps that need to be taken, and all information required, should a transformer fail. This includes logistical information, such as contact information for initiating unit repair and replacement activity, all unit data necessary for such activity, all necessary transportation details, permits, limitations, etc. Further, the service provider may perform all necessary pre-engineering required to expedite the removal of the failed unit for repair/replacement, and the movement, placement, and electrical connection of any lease transformer, as applicable.

The TRP may additionally include transformer condition-based maintenance, including performing preventive maintenance, inspection, testing and reporting on each of the member transformers.

The TRP may provide for all aspects of transportation of the replacement GSU transformer to the operator's site, including necessary permits for the replacement GSU transformer. Such preparation may include obtaining pre-permits for emergency transportation of the portable GSU from the applicable transportation agencies to minimize cycle time required for the permit process. Also, provide the transportation to/from customer sites via roadways or other modes of transportation (railroad).

The TRP may also provide technical advisory services for all deployment events, such as disassembly/removal of customer GSU, installation of portable GSU, electrical tests/energize/deenergize units, repair/replacement proposals, etc.

As part of the TRP lease program, the temporary lease transformers are stored and maintained by the service provider. Also, the TRP lease program may be maintained by personnel to manage the various levels of transformer coverage provided under the program, monitor transformer maintenance and reporting, and to act as the single point of contact for facilities with member transformers, and the various service provider transformer repair, engineering, and headquarters project management teams.

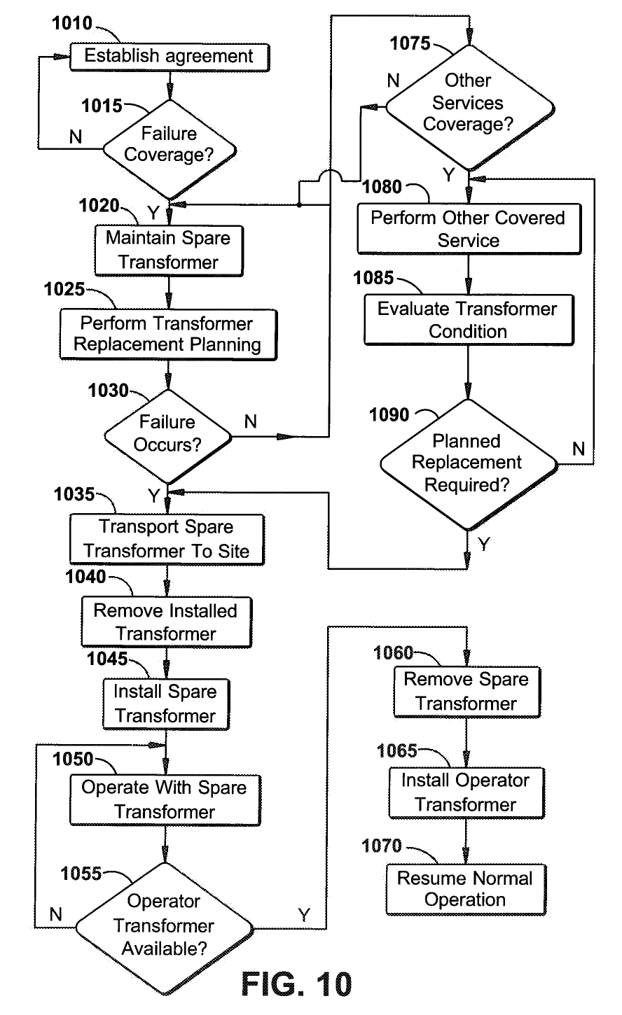

FIG. 10 illustrates a flowchart representing a method for maintaining power transmission through a generator stepup (GSU) transformer. In step 1010 an agreement is established between a service provider and an operator for supporting continuity of power transmission through an installed GSU transformer. The arrangement may include charging a periodic fee failure coverage including maintaining availability of at least one phase of a replacement GSU transformer and for expediting installation of at least one phase of a replacement GSU transformer for a failed unit of the operator. The agreement may also include charging a rental fee for use of the replacement GSU transformer. In addition to the failure coverage, the agreement may also provide for charging a fee for services including at least one of assessing initial condition of the installed GSU transformer; continuing inspection; continuing monitoring of the installed GSU transformer; performing preventive maintenance on the installed GSU transformer; and providing technical advisory services for installation and removal of the replacement GSU transformer.

In step 1015, it is determined if failure coverage is in place, then the service provider will maintain a spare replacement transformer for the operator in step 1020. In step 1025 the service provider will also perform transformer replacement planning in preparation for the occurrence of a failure.

If no failure occurs in step 1030, the service provider will continue maintaining the spare transformer per step 1020 available. It will also be determined in step 1075 whether the arrangement between the service provider and the operator has other covered services, as previously described. The covered services will be performed by the service provider on the operator's transformers in step 1080. The services may include diagnostic, continuing monitoring, and continuing maintenance, which will assist in maintaining the transformer in a safe and continued operating condition. Further under covered services, the service provide will evaluate the installed transformer condition in step 1085 and determine in step 1090 if the installed transformer needs to be taken out of service. If removal from service is not required, then the service provide continues with performance of the other covered services per step 1080.

If removal from service is required for the installed transformer in step 1090 or a failure has occurred in step 1030, then in step 1035, the spare transformer is transported to the operator site. For a scheduled replacement, the transformer will be shipped to the operator site in advance. In step 1040, the installed transformer is removed. In step 1045, the spare transformer is installed. In step 1050, operation with the spare transformer is restored. It is determined in step 1055 if the operator's transformer is available for return to service. If the operator transformer is available, then in step 1060 the spare transformer is removed. In step 1065, the operator's transformer is installed and in step 1070, normal operation is resumed. If, in step 1055, the operator transformer is not available, then operation continues with the spare transformer until such time as the operator transformer becomes available through repair or procurement.

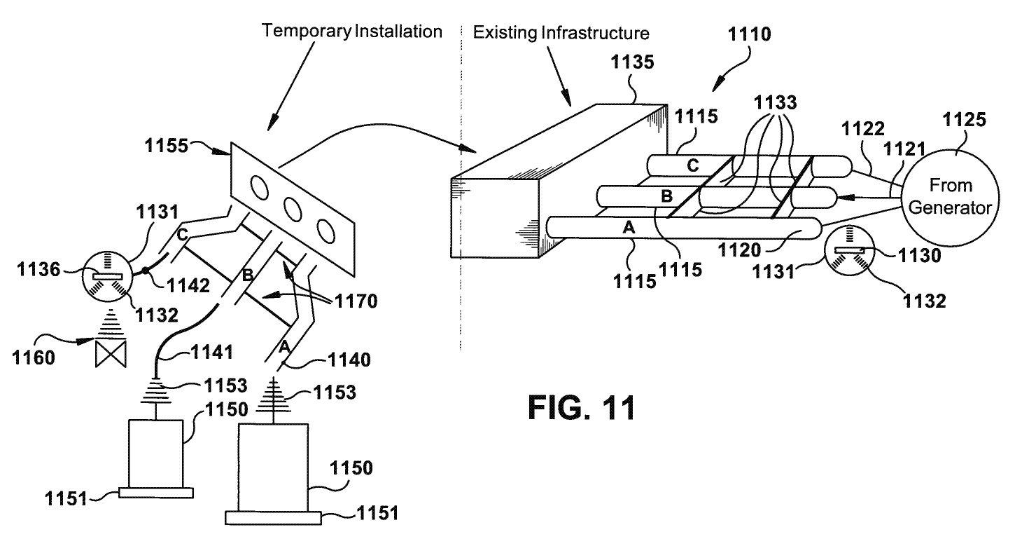

Pre-engineering is intended to expedite installation of the portable single-phase GSU transformers when they reach the operator's power plant site. Typically, the low voltage, high-current generator side of the installed GSU transformer is connected to the power plant generator by iso-phase buswork. FIG. 11 illustrates a connection for the portable single-phase GSU transformers to the installed iso-phase bus infrastructure. The existing iso-phase bus infrastructure 1110 includes a bus 1115 for each output phases A 1120, B 1121, C 1122 of an installed generator 1125. The bus 1115 includes a center conductor 1130 supported within the iso-phase conduit 1131 by insulators 1132. Shorting plates 1133 tie the iso-phase conduit together at a generator end and at a junction end. The junction 1135 provides for a mechanical connection (internal-not shown) of the iso-phase bus 1115 from the generator 1125 to the installed transformer (not shown).

When an installed GSU transformer must be removed to make way for a portable replacement, the iso-phase bus between the junction and the installed GSU transformer is removed. A temporary connection plate 1155 is attached to the junction for accepting temporary iso-phase buses for each output phase A 1140, B 1141 and C 1142 for the portable single-phase GSU transformer 1150. The portable single-phase GSU transformers 1150 are mounted on pads 1151 or other suitable placement for connection to the junction. The iso-phase buses are connected from the low voltage bushing 1153 for each the portable single-phase GSU transformers to the junction, where a connection is made with respective iso-phase buses on the generator side. A supporting structure 1160 may be provided for each iso-phase bus. Shorting plates 1170 tie the iso-phase conduit together at a generator end and at a junction end

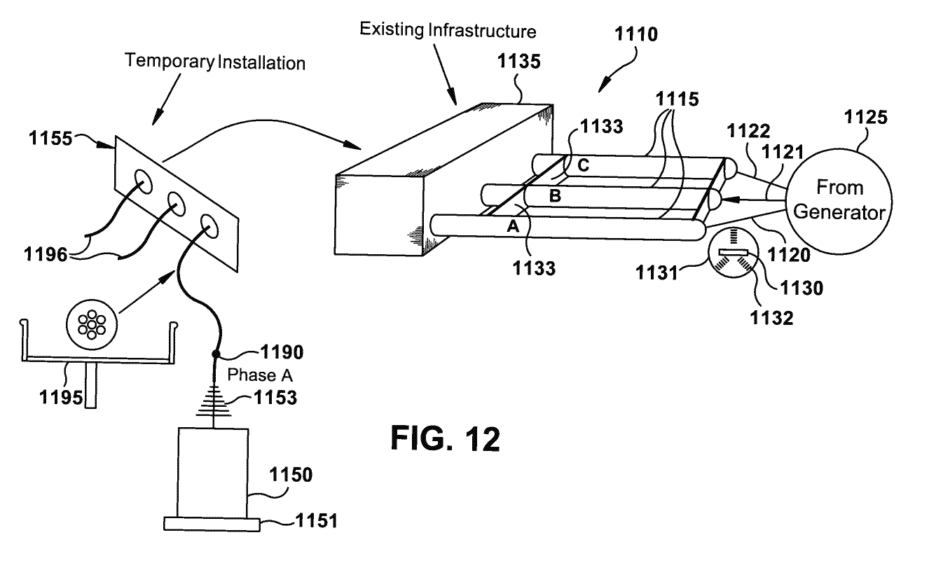

As an alternative, the connections between the existing iso-phase infrastructure may be made with cable connections as illustrated in FIG. 12. One or more high capacity cables 1190 may be connected between the low voltage bushing 1153 for each of the portable single-phase GSU transformers 1150 and the respective connection at the junction 1135 with the existing iso-phase infrastructure 1110 through the temporary connection plate. One or more cable trays 1195 may be provided to maintain the cables 1190 off the ground.

Pre-engineering may provide for layout and preparation of drawings for the iso-phase bus connections between the existing infrastructure 1110 and the portable single-phase GSU transformers 1150. Further, some operators may find it advantageous to have the connection hardware built and stored on site to limit replacement time for failed installed units.

1. A method for maintaining power transmission supplied through an installed generator stepup (GSU) transformer adapted for at least one of a primary generating station and a primary substation, comprising:
providing at least one portable spare single-phase GSU transformer of suitable rating to replace at least one phase of an installed GSU transformer, wherein the portable spare single-phase GSU transformer is sized to fit aboard an individual on-the-road trailer according to national transportation standards for on-road transport; and
storing the at least one portable spare single-phase GSU transformer in at least one central location until needed to perform a replacement.

2. The method for maintaining power transmission supplied through an installed GSU transformer according to claim 1, the step of providing further comprises: providing the portable spare single-phase GSU transformer with a rating to replace at least one of a full load and a partial load for the installed GSU transformer.

3. The method for maintaining power transmission supplied through an installed GSU transformer according to claim 1, further comprising: determining an occurrence for at least one of a failure and a planned shutdown for the installed GSU transformer.

4. The method for maintaining power transmission supplied through an installed GSU transformer according to claim 3, further comprising: transporting each individual portable spare single-phase GSU transformer via an on-the-road trailer to a site of the at least one of failure and planned replacement.

5. The method for maintaining power transmission supplied through an installed GSU transformer according to claim 4, further comprising: supplementing the installed GSU transformer with at least one portable spare single-phase GSU transformer connected in parallel with at least one phase of the installed GSU transformer.

6. The method for maintaining power transmission supplied through an installed GSU transformer according to claim 4, further comprising:
replacing at least one phase of the installed GSU transformer with the at least one phase of portable spare single-phase GSU transformer wherein the required load on the phase of the installed GSU transformer is substantially below the rated load for the of the portable spare single-phase GSU transformer; and
connecting a reactance in line with each phase of the portable spare single-phase GSU transformer.

7. The method for maintaining power transmission supplied through an installed GSU transformer according to claim 4, further comprising:
replacing at least one phase with one phase of the portable spare single-phase GSU transformer wherein the load rating of the installed GSU transformer exceeds load rating of portable installed GSU; and
operating the at least portable spare single-phase GSU transformer up to its load rating.

8. The method for maintaining power transmission supplied through an installed GSU transformer according to claim 4, further comprising:
replacing at least one phase of the installed GSU transformer with a plurality of parallel spare single-phase portable GSU transformers;
operating up to the combined load rating of the plurality of parallel spare single-phase portable GSU transformers.

9. A method for maintaining power transmission supplied through an installed generator stepup (GSU) transformer adapted for at least one of a primary generating station and a primary substation, comprising:
establishing an arrangement between a service provider and an operator for supporting continuity of power transmission through an installed GSU transformer;
maintaining availability of at least one phase of a portable single-phase GSU transformer for replacing at least one phase an installed GSU transformer; and
providing services to the power generating entity for at least one of maintaining operability of the installed GSU transformer and expediting installation of at least one phase of a portable single-phase GSU transformer for at least one phase of the installed GSU transformer.

10. The method according to claim 9, the step of providing services to the operator comprising: providing outage planning for expedited replacement of at least one phase of the installed GSU transformer.

11. The method according to claim 10, wherein the step of providing outage planning comprises at least one of:
compiling logistical information for replacement of at least one phase of the installed GSU transformer with at least one phase of the replacement GSU transformer;
establishing requirements for transportation of at least one phase of a replacement GSU transformer; and
pre-engineering at least one of removal of the installed GSU transformer;
transportation of the replacement GSU unit; and installation of the replacement GSU transformer.

12. The method according to claim 9, the step of providing services to the operator further comprising at least one of:
assessing an initial condition for the installed GSU transformer,
continuing monitoring of a condition for the installed GSU transformer;
performing preventive maintenance on the GSU transformer, including at least one of inspecting on the GSU transformer; testing of the GSU transformer; reporting on the condition of the GSU transformer; and recommending outage of the GSU transformer; and
obtaining pre-permitting for transport of the at least one phase of the portable spare GSU transformer.

13. The method according to claim 9, the step of providing services to the operator comprising:
delivering at least one portable single-phase GSU transformer to a site incurring an outage of the installed GSU transformer by at least one of an on-the-road trailer, a railway; and barge;
removing the installed GSU transformer from service;
placing the at least one portable single-phase GSU transformer in service at the site; and
removing the at least one portable single-phase GSU transformer; and
restoring to service a GSU transformer provided by the operator.

14. The method according to claim 9, the step of establishing an arrangement comprising:
charging a periodic fee for at least one of maintaining availability of at least one phase of a replacement GSU transformer and for expediting installation of at least one phase of a replacement GSU transformer; and
charging a rental fee for use of the replacement GSU transformer.

15. The method according to claim 14, further comprising:
charging a fee for services including at least one of assessing initial condition of the installed GSU transformer; continuing inspection; continuing monitoring of the installed GSU transformer; performing preventive maintenance on the installed GSU transformer; and providing technical advisory services for installation and removal of the replacement GSU transformer.

16. The method according to claim 9, the step of establishing an arrangement comprising: charging a one-time fee for use of the at least one portable single-phase GSU transformer and for transportation of the GSU transformer to a site of the operator.

17. The method according to claim 9, the step of establishing an arrangement further comprising: providing availability-type guarantees to the operator including at least one of a return to service time and an on-site delivery time.

18. A portable single-phase generator stepup (GSU) transformer arrangement adapted for replacing one phase of a three-phase GSU transformer for one of a primary generating station and a primary substation, comprising:
a portable single-phase GSU transformer for at least one of a power generating station and a primary substation, sized to fit aboard an on-the-road trailer according to national transportation standards.

19. The portable single-phase GSU transformer arrangement according to claim 18, wherein the national transportation standards comprises: U.S. Department of Transportation (U.S.D.O.T.) standards for height, width and weight.

20. The portable single-phase GSU transformer arrangement according to claim 18, further comprising:
current-limiting reactors in fine with the portable single-phase GSU transformer and adapted to limit fault current for operation at below rated MVA loads.

21. The portable single-phase GSU transformer arrangement according to claim 18, further comprising:
a plurality of portable single-phase GSU transformers connected in parallel with an installed three-phase GSU transformer and adapted to supplement a power output from the installed GSU transformer.

22. The portable single-phase GSU transformer arrangement according to claim 18, further comprising:
a plurality of portable single-phase GSU transformers connected in parallel replacing each phase of the installed three-phase GSU transformer and adapted for operation of each phase above the rating of the individual portable single-phase GSU transformer.

23. The portable single-phase GSU transformer arrangement according to claim 18, further comprising:
a spare portable single-phase GSU transformer replacing one phase of a three-phase bank of installed single-phase GSU transformers.
